(19) United States
(12) Patent Application Publication
(10) Pub. No.: US 2021/0036066 A1
(43) Pub. Date: Feb. 4, 2021

(54) METHOD AND APPARATUS FOR DETERMINING SUBPIXEL ARRANGEMENT OF ORGANIC LIGHT EMITTING DISPLAY PANEL, AND COMPUTER READABLE STORAGE MEDIUM

(71) Applicants: Chengdu BOE Optoelectronics Technology Co., Ltd., Chengdu (CN); BOE Technology Group Co., Ltd., Beijing (CN)

(72) Inventors: Chang Luo, Beijing (CN); Fengli Ji, Beijing (CN); Jianpeng Wu, Beijing (CN)

(73) Assignees: Chengdu BOE Optoelectronics Technology Co., Ltd., Chengdu (CN); BOE Technology Group Co., Ltd., Beijing (CN)

(21) Appl. No.: 16/926,901

(22) Filed: Jul. 13, 2020

(30) Foreign Application Priority Data
Jul. 29, 2019 (CN) 201910688916.3

(51) Int. Cl. H01L 27/32; H01L 51/00; G06F 30/392

(52) U.S. Cl. CPC H01L 27/3218; G06F 30/392; H01L 27/3216; H01L 51/0011

(57) ABSTRACT

The present disclosure relates to a method and an apparatus for determining a subpixel arrangement of an organic light emitting display panel, and a computer readable storage medium. The subpixel arrangement determining method includes: determining arrangement parameters of the first subpixel, the second subpixel, and the third subpixel, according to a side length of the virtual square, a spacing between the third subpixel and an adjacent first subpixel, a spacing between the third subpixel and an adjacent second subpixel, a ratio of aperture ratios of the first subpixel, the second subpixel and the third subpixel, and arrangement constraint conditions of the first subpixel, the second subpixel, and the third subpixel, so that the aperture ratio of the first subpixel is not less than a target aperture ratio.

### CROSS-REFERENCE TO RELATED APPLICATIONS

This application is based on and claims the priority to the Chinese Patent Application No. 201910688916.3 filed on Jul. 29, 2019, the present disclosure of which is incorporated hereby as a whole into the present disclosure.

### TECHNICAL FIELD

The present disclosure relates to the technical field of display, and particularly to a method and an apparatus for determining a subpixel arrangement of an organic light emitting display panel, and a computer readable storage medium.

### BACKGROUND

The organic light emitting display device has been listed as a very promising next generation display technology due to its advantages such as thinness, light weight, wide viewing angle, active light emission, continuously adjustable light emission color, low cost, fast response speed, low energy consumption, low driving voltage, wide working temperature range, simple production process, high light emitting efficiency, and flexible display.

In the related art, manual valuation and multiple adjustment are generally adopted for a display panel of the organic light emitting display device to design parameters of subpixel arrangement. Such a design mode is time-consuming and labor-consuming, has a low accuracy, and cannot maximize the aperture ratio, thereby affecting the service life and the display quality of the display device.

### SUMMARY

The present disclosure provides a method and apparatus for determining a subpixel arrangement of an organic light emitting display panel, and computer readable storage medium.

According to an aspect of the present disclosure, there is provided a method for determining a subpixel arrangement of an organic light emitting display panel, wherein the organic light emitting display panel comprises a first subpixel, a second subpixel and a third subpixel, the first subpixel and the second subpixel are sequentially arranged at four vertexes of a virtual square in a clockwise direction, the first subpixel and the second subpixel are approximately square and a diagonal line of the first subpixel and a diagonal line of the second subpixel extend along one side of the virtual square, the third subpixel is arranged at a center of the virtual square, the third subpixel has a first symmetry axis extending along one of diagonal lines of the virtual square and a second symmetry axis extending along the other diagonal line of the virtual square, the method for determining the subpixel arrangement comprising: determining arrangement parameters of the first subpixel, the second subpixel, and the third subpixel, according to a side length of the virtual square, a spacing between the third subpixel and an adjacent first subpixel, a spacing between the third subpixel and an adjacent second subpixel, a ratio of aperture ratios of the first subpixel, the second subpixel and the third subpixel, and arrangement constraint conditions of the first subpixel, the second subpixel, and the third subpixel, so that the aperture ratio of the first subpixel is not less than a target aperture ratio.

According to another aspect of the present disclosure, there is provided a method for manufacturing an organic light emitting display panel, comprising:
determining the arrangement parameters of the first subpixel, the second subpixel and the third subpixel according to a previous method for determining a subpixel arrangement;
determining characteristic parameters of a mask plate used for evaporating an organic material layer corresponding to each subpixel of the first subpixel, the second subpixel and the third subpixel, according to the determined arrangement parameters; and
respectively forming the organic material layer corresponding to each subpixel using the mask plate having the determined characteristic parameters.

According to some other aspect of the present disclosure, there is provided an organic light emitting display panel obtained according to the previous manufacturing method.

According to still another aspect of the present disclosure, there is provided an apparatus for determining a subpixel arrangement of an organic light emitting display panel, comprising: a memory, and a processor coupled to the memory, the processor configured to perform the method for determining a subpixel arrangement according to any of the previous embodiments based on instructions stored in the memory.

According to yet another aspect of the present disclosure, there is provided a non-transient computer readable storage medium having stored thereon a computer program, which when executed by a processor, implements the method for determining a subpixel arrangement according to any of the previous technical solutions.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate the embodiments of the present disclosure and, together with the description, serve to explain the principles of the present disclosure.

The present disclosure will be understood more clearly according to the following detailed description with reference to the accompanying drawings.

FIG. 1 is a schematic view illustrating a diamond arrangement of some subpixels according to an embodiment of the present disclosure;

FIG. 2 is a schematic cross-sectional view illustrating organic light emitting diode devices corresponding to some subpixels according to an embodiment of the present disclosure;

FIG. 3 is a flowchart illustrating a method for determining a subpixel arrangement of an organic light emitting display panel according to an embodiment of the present disclosure;

FIG. 4a is a schematic view illustrating a portion of arrangement parameters of the subpixels shown in FIG. 1;

FIG. 4b is a schematic view of another portion of arrangement parameters of the subpixels shown in FIG. 1;

FIG. 5 is a schematic view illustrating an iterative flow for solving the arrangement parameters in an embodiment of the present disclosure;

FIG. 6 is a schematic view illustrating a diamond arrangement of some subpixels according to another embodiment of the present disclosure;

FIG. 7 is a schematic view illustrating a diamond arrangement of some subpixels according to still another embodiment of the present disclosure;

FIG. 8 is a schematic view illustrating a diamond arrangement of some subpixels according to yet another embodiment of the present disclosure;

FIG. 9a is a block diagram illustrating an apparatus for determining a subpixel arrangement of an organic light emitting display panel according to an embodiment of the present disclosure;

FIG. 9b is a block diagram illustrating an apparatus for determining a subpixel arrangement of an organic light emitting display panel according to another embodiment of the present disclosure;

FIG. 10 is a block diagram of a computer system according to an embodiment of the present disclosure.

Please be appreciated that, the sizes of various portions shown in the accompanying drawings are not drawn to actual scale. Furthermore, identical or similar reference numerals are used to refer to identical or similar members.

### DETAILED DESCRIPTION

Various exemplary embodiments of the present disclosure will be described in detail with reference to the accompanying drawings in the following. The following description of the exemplary embodiments is merely illustrative in nature and is in no way intended to limit this disclosure, its application, or uses. The present disclosure may be implemented in many different forms and is not limited to the embodiments described herein. These embodiments are provided merely for making the present disclosure thorough and complete, and sufficiently expressing the scope of the present disclosure to one of ordinary skill in the art. It should be noted that the relative arrangement of the components and steps set forth in these embodiments are interpreted to be merely illustrative instead of restrictive, unless it is specifically stated otherwise.

All terms (including technical or scientific terms) used in this disclosure have the same meanings as understood by one of ordinary skill in the art, unless otherwise specifically defined. It should also be understood that the terms defined in common dictionaries should be interpreted as having meanings consistent with their meanings in the context of the relevant technologies, but should not be interpreted with idealized or extremely formalized meanings, unless otherwise expressly defined herein.

Techniques, methods and apparatus as known by one of ordinary skill in the relevant art may not be discussed in detail, but are intended to be regarded as a part of the specification where appropriate.

There are various arrangements of subpixels of the organic light emitting display panel. Compared with the traditional red, green and blue arrangement, the diamond arrangement can display more pixel units through subpixel borrowing, i.e., display an image with a higher resolution, and thus is widely applied.

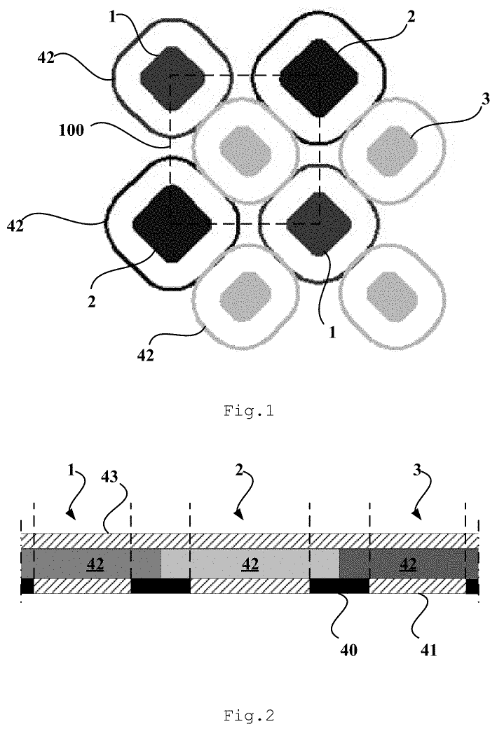

As shown in FIG. 1, an organic light emitting display panel with a diamond subpixel arrangement comprises: a first subpixel 1, a second subpixel 2, a first subpixel 1, a second subpixel 2 sequentially arranged at four vertexes of a virtual square 100 in a clockwise direction, and a third subpixel 3 arranged at a center of the virtual square 100, wherein the first subpixel 1 and the second subpixel 2 are approximately square, a diagonal line extends along one side of the virtual square 100, the third subpixel 3 has a first symmetry axis and a second symmetry axis, the first symmetry axis extends along one of diagonal lines of the virtual square 100, and the second symmetry axis extends along the other diagonal line of the virtual square 100. The first subpixel 1, the second subpixel 2 and the third subpixel 3 are different in color from each other.

Each virtual square 100 corresponds to one pixel unit of the organic light emitting display panel. The first subpixel 1 and the second subpixel 2 are substantially square, which means that the overall shape is square, but four corners may be specifically a round chamfer or an oblique chamfer. As can be seen from the figure, each pixel unit comprises two ¼-area first subpixels 1, two ¼-area second subpixels 2, and one complete third subpixel 3.

Each subpixel of the organic light emitting display panel is an effective light emitting portion of an OLED (Organic Light-Emitting Diode) device. As shown in FIG. 2, the OLED device mainly includes an anode 41, an organic material layer 42, and a cathode 43, which are sequentially disposed. The organic material layer 42 comprises an organic light emitting layer, which can be formed by evaporation. Anodes 41 of various OLED devices are spaced apart by a pixel defining layer 40, and cathodes 43 of all or some of the OLED devices are connected together to have an equipotential. When an electric field is established between the anode 41 and the cathode 43, the organic material layer 42 emits visible light. The organic material layers 42 corresponding to the first subpixel 1, the second subpixel 2 and the third subpixel 3 emit different colors. In the manufacturing of the organic material layer 42 of the organic light emitting display panel, the organic material layer 42 corresponding to each first subpixel is formed through a first evaporation process, then the organic material layer 42 corresponding to each second subpixel is formed through a second evaporation process, and then the organic material layer 42 corresponding to each third subpixel is formed through a third evaporation process, wherein one mask plate is respectively required in the three evaporation processes. The organic material layer 42 has the same shape as the corresponding subpixel and their geometric centers coincide, but the size of the organic material layer 42 is different from that of the corresponding subpixel, so the edge of the organic material layer is located outside that of the corresponding subpixel.

An aperture ratio of the organic light emitting display panel may be understood as a percentage of an area of the organic light emitting display panel occupied by a sum of areas of the respective subpixels. An aperture ratio of the subpixel may be understood as a percentage of an area of the pixel unit occupied by a total area of a certain color of subpixels in the pixel unit.

FIG. 1 shows a diamond subpixel arrangement in an ideal state, in which the organic material layers of adjacent OLED devices have neither gaps nor overlaps, and aperture ratios of different colors of subpixels are in a certain ratio and are maximized in the ideal state.

The inventors of the present application found in the process of implementing the embodiments of the present disclosure that, in the related art, designers design the subpixel arrangement of the organic light emitting display panel using manual valuation and multiple adjustment, which is time-consuming and labor-consuming, has a low accuracy, and cannot realize maximization of the aperture ratio, thereby affecting the service life of the OLED device and the display quality of the organic light emitting display device.

To solve this technical problem, the embodiments of the present disclosure provide a method and an apparatus for determining a subpixel arrangement of an organic light emitting display panel, and a computer readable storage medium.

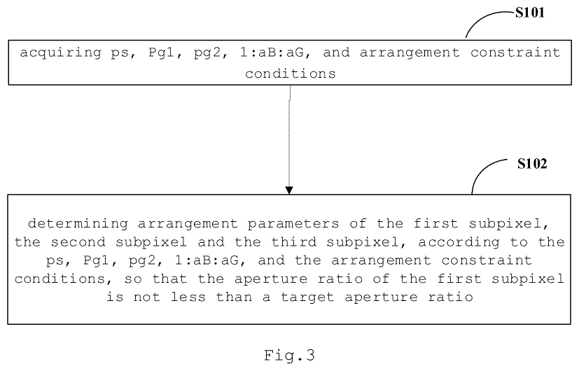

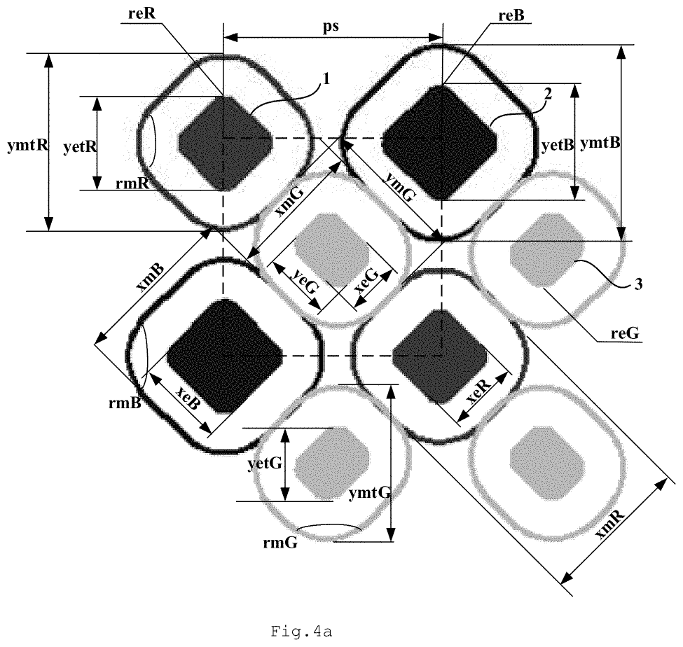

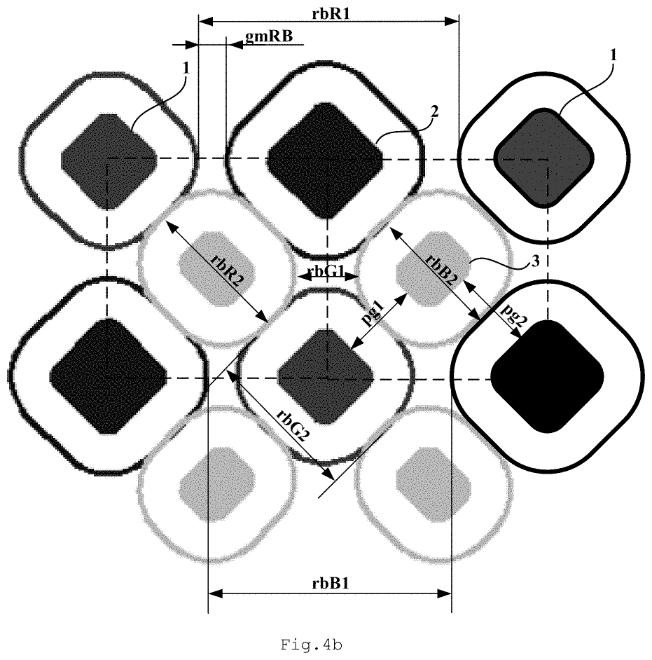

As shown in FIGS. 3, 4a and 4b, in view of the diamond subpixel arrangement, an embodiment of the present disclosure provides a method for determining a subpixel arrangement of an organic light emitting display panel. The subpixel arrangement determining method comprises steps S101 to S102.

In the step S101, the following parameters are acquired: a side length ps of the virtual square 100, a spacing pg1 between the third subpixel 3 and an adjacent first subpixel 1, a spacing pg2 between the third subpixel 3 and an adjacent second subpixel 2, a ratio 1:aB:aG of the aperture ratios of the first subpixel 1, the second subpixel 2 and the third subpixel 3, and arrangement constraint conditions of the first subpixel 1, the second subpixel 2, and the third subpixel 3.

The arrangement constraint conditions of the first subpixel 1, the second subpixel 2 and the third subpixel 3 can be understood as: numerical ranges of the first subpixel 1, the second subpixel 2, the third subpixel 3, and the respective organic material layers in terms of geometric dimensions, spacing setting, and the like, as shown in the following Formula 4 to Formula 9. The setting of the arrangement constraint condition needs to consider not only product design requirements but also a processing precision which can be achieved by the mask plate.

The above parameters and arrangement constraint conditions to be acquired, as known quantities, may be determined by a designer according to design requirements of the subpixel arrangement of the organic light emitting display panel, and then input into a computer. The parameters and the arrangement constraint conditions can also be stored in the computer and extracted by the computer.

In step S102, arrangement parameters of the first subpixel 1, the second subpixel 2, and the third subpixel 3 are determined, according to the side length ps of the virtual square 100, the spacing pg1 between the third subpixel 3 and an adjacent first subpixel 1, the spacing pg2 between the third subpixel 3 and an adjacent second subpixel 2, the ratio 1:aB:aG of the aperture ratios of the first subpixel 1, the second subpixel 2 and the third subpixel 3, and arrangement constraint conditions of the first subpixel 1, the second subpixel 2, and the third subpixel 3, so that the aperture ratio arR of the first subpixel 1 is not less than a target aperture ratio.

For the diamond subpixel arrangement design shown in FIGS. 4a and 4b, the arrangement parameters of the first subpixel 1, the second subpixel 2 and the third subpixel 3 may include a side length xeR of the first subpixel 1, a value of chamfers reR of the first subpixel 1, a short side length xeG of the third subpixel 3, a value of chamfers reG of the third subpixel 3 and a value of chamfers reB of the second subpixel 2. These arrangement parameters xeR, reR, xeG, reG, reB should make the aperture ratio of the first subpixel 1 not less than the target aperture ratio set by the designer according to design requirements. Since the ratio 1:aB:aG of the aperture ratios of the first subpixel 1, the second subpixel 2 and the third subpixel 3 is a known quantity, the aperture ratios of the second subpixel 2 and the third subpixel 3 also reach the design requirements at the same time.

After the arrangement parameters xeR, reR, xeG, reG, and reB are determined, other arrangement parameters and subpixel areas of the first subpixel 1, the second subpixel 2, and the third subpixel 3 may be calculated in combination with the aforementioned known quantities, and specific characteristic parameters of the mask plate used for evaporating the organic material layer, e.g., an aperture dimension and a chamfer of the mask plate, may also be determined.

In some embodiments of the present disclosure, determining arrangement parameters of the first subpixel 1, the second subpixel 2, and the third subpixel 3 so that the aperture ratio of the first subpixel 1 is not less than a target aperture ratio comprises: determining the arrangement parameters of the first subpixel 1, the second subpixel 2, and the third subpixel 3 so that the aperture ratio of the first subpixel 1 is maximized.

The arrangement parameters of the first subpixel 1, the second subpixel 2 and the third subpixel 3 are such that the aperture ratio of the first subpixel 1 is maximized, while the aperture ratios of the second subpixel 2 and the third subpixel 3 are also maximized. The organic light emitting display panel designed and manufactured according to the arrangement parameters of the embodiment has a better display effect and a relatively longer service life due to the maximization of the aperture.

In the embodiment of the present disclosure, the colors of the first subpixel 1, the second subpixel 2, and the third subpixel 3 are not particularly limited.

In the diamond subpixel arrangement design shown in FIGS. 4a and 4b, the first subpixel 1 is a red subpixel, the second subpixel 2 is a blue subpixel, and the third subpixel 3 is a green subpixel. Under the condition of the same area, the service life of the blue subpixel is the shortest, and the service life of the red subpixel is slightly shorter than that of the green subpixel, therefore, in the diamond subpixel arrangement design, the area of the blue subpixel can be designed to be the largest among the three, and the area of the green subpixel can be equivalent to or slightly smaller than the area of the red subpixel. In this way, the current density of the blue subpixel can be reduced, and the rate of attenuation thereof can be decreased, such that the lifetime of the blue subpixel matches with that of the red and green subpixels.

In the embodiment shown in FIGS. 4a and 4b, the organic material layers of the first subpixel 1, the second subpixel 2 and the third subpixel 3 are respectively prepared by a mask plate evaporation method, each subpixel has the same shape as the corresponding organic material layer and their geometric centers coincide with each other, and an edge of each subpixel is located inside an edge of the corresponding organic material layer; wherein the third subpixel 3 is substantially rectangular, that is, the whole third subpixel 3 is rectangular; four corners of the first subpixel 1, the second subpixel 2 and the third subpixel 3 have round chamfers, and the arrangement parameters of the first subpixel 1, the second subpixel 2 and the third subpixel 3 can be determined according to the following relational expressions:

$$\begin{matrix}\{ \begin{matrix}xmR = xeR + pg 1 \\ yetR = \sqrt{2} xeR - 2 ( \sqrt{2} - 1 ) * reR \\ ymtR = \sqrt{2} xmR - 2 ( \sqrt{2} - 1 ) * rmR \\ seR = {xeR}^{2} - ( 4 - π ) * {reR}^{2} \\ α rR = seR / 2 p {s}^{2}\end{matrix} & Formula 1 \\ \{ \begin{matrix}xmB = xeB + pg 2 \\ yetB = \sqrt{2} xeB - 2 ( \sqrt{2} - 1 ) * reB \\ ymtB = \sqrt{2} xmB - 2 ( \sqrt{2} - 1 ) * rmB \\ seB = {xeB}^{2} - ( 4 - π ) * {reB}^{2} = seR * α B \\ α rB = seB / 2 p {s}^{2}\end{matrix} & Formula 2 \\ \{ \begin{matrix}xmG = xeG + pg 2 \\ ymG = yeG + pg 1 \\ yetG = \sqrt{2} xeG + \frac{yeG - xeG}{\sqrt{2}} - 2 ( \sqrt{2} - 1 ) * reG \\ ymtG = \sqrt{2} xmG + \frac{ymG - xmG}{\sqrt{2}} - 2 ( \sqrt{2} - 1 ) * rmG \\ seG = xeG * yeG - ( 4 - π ) * {reG}^{2} = seR * α G \\ α rG = seG / p {s}^{2}\end{matrix} & Formula 3 \\ \{ \begin{matrix}gmRB \geq 0 \\ xmG + xmR \leq \sqrt{2} p s \\ ymG + xmB \leq \sqrt{2} p s\end{matrix} & Formula 4 \\ \{ \begin{matrix}rbR 1 = p s * 2 - ymtR \geq rib \\ rbR 2 = \sqrt{2} p s - xmR \geq rib\end{matrix} & Formula 5 \\ \{ \begin{matrix}rbR 1 = p s * 2 - ymtR \geq rib \\ rbR 2 = \sqrt{2} p s - xmR \geq rib\end{matrix} & Formula 6 \\ \{ \begin{matrix}rbG 1 = p s - ymtG \geq rib \\ rbG 2 = \sqrt{2} p s - xmG \geq rib\end{matrix} & Formula 7 \\ \{ \begin{matrix}xeR \geq slot \\ xeG \geq slot \\ xeB \geq slot\end{matrix} & Formula 8 \\ \{ \begin{matrix}rmR \geq rc \\ rmB \geq rc \\ rmG \geq rc\end{matrix} & Formula 9\end{matrix}$$

wherein xeR is a side length of the first subpixel, xeB is a side length of the second subpixel, xeG is a short side length of the third subpixel, and yeG is a long side length of the third subpixel; xmR is a side length of the organic material layer corresponding to the first subpixel, xmB is a side length of the organic material layer corresponding to the second subpixel, xmG is a short side length of the organic material layer corresponding to the third subpixel, and ymG is a long side length of the organic material layer corresponding to the third subpixel;
yetR is a diagonal length of the first subpixel, yetB is a diagonal length of the second subpixel, and yetG is a diagonal length of the third subpixel;
ymtR is a diagonal length of the organic material layer corresponding to the first subpixel, ymtB is a diagonal length of the organic material layer corresponding to the second subpixel, and ymtG is a diagonal length of the organic material layer corresponding to the third subpixel;
reR is a value of chamfers of the first subpixel, reB is a value of chamfers of the second subpixel, and reG is a value of chamfers of the third subpixel;
rmR is a value of chamfers of the organic material layer corresponding to the first subpixel, rmB is a value of chamfers of the organic material layer corresponding to the second subpixel, and rmG is a value of chamfers of the organic material layer corresponding to the third subpixel;
SeR is an area of the first subpixel, SeB is an area of the second subpixel, and SeG is an area of the third subpixel; arR is an aperture ratio of the first subpixel, arB is an aperture ratio of the second subpixel, and arG is an aperture ratio of the third subpixel;
gmRB is a spacing between the organic material layers respectively corresponding to adjacent first subpixel and second subpixel, rbR1 is a spacing between the organic material layers corresponding to two first subpixels adjacent in a row direction, rbR2 is a spacing between the organic material layers corresponding to two first subpixels adjacent in a diagonal direction of the virtual square, rbB1 is a spacing between the organic material layers corresponding to two second subpixels adjacent in the row direction, rbB2 is a spacing between the organic material layers corresponding to two second subpixels adjacent in the diagonal direction of the virtual square, rbG1 is a spacing between the organic material layers corresponding to two third subpixels adjacent in the row direction, and rbG2 is a spacing between the organic material layers corresponding to two third subpixels adjacent in the diagonal direction of the virtual square;
ps is a side length of the virtual square and is a known quantity, pg1 is a spacing between the third subpixel and an adjacent first subpixel and is a known quantity, pg2 is a spacing between the third subpixel and an adjacent second subpixel and is a known quantity, a ratio of the aperture ratios of the first subpixel, the second subpixel and the third subpixel is 1:aB:aG and is a known quantity, rib is a minimum allowable spacing between two adjacent apertures of the mask plate, slot is a minimum allowable width of the aperture of the mask plate, and rc is a minimum allowable value of chamfers of the aperture of the mask plate.

In some embodiments of the present disclosure, the side length xeR of the first subpixel 1, the value of chamfers reR of the first subpixel 1, the short side length xeG of the third subpixel 3, the value of chamfers reG of the third subpixel 3, and the value of chamfers reB of the second subpixel 2 in the geometric model shown in FIGS. 4a and 4b are obtained through iterative computation of the computer.

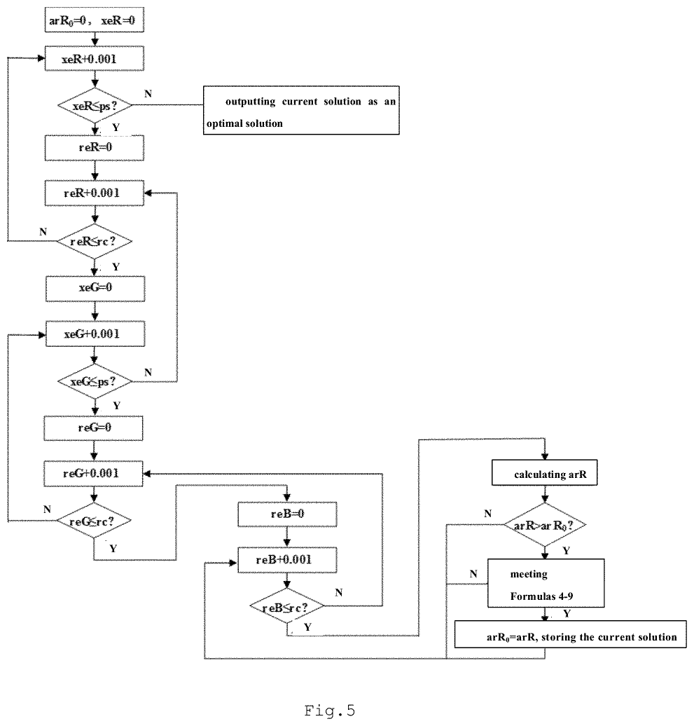

The iterative computation flow is shown in FIG. 5. The xeR, the reR, the xeG, the reG and the reB are used as direct iteration variables, the arR is used as an indirect iteration variable, and the iteration relation and the constraint conditions are as the previous Formulas 1-9. The iteration variables each starts an iteration from an initial value (set empirically, e.g. set to 0), and one iteration step (empirically set, e.g. set to 0.001 micron) is increased each time. If a certain iteration variable is within a limit range, an iteration of the next iteration variable is continued, and otherwise, the iteration of the previous iteration variable is returned to. The iteration is repeated in this way until the calculated aperture ratio takes a maximum value, and the current solution is output as an optimal solution.

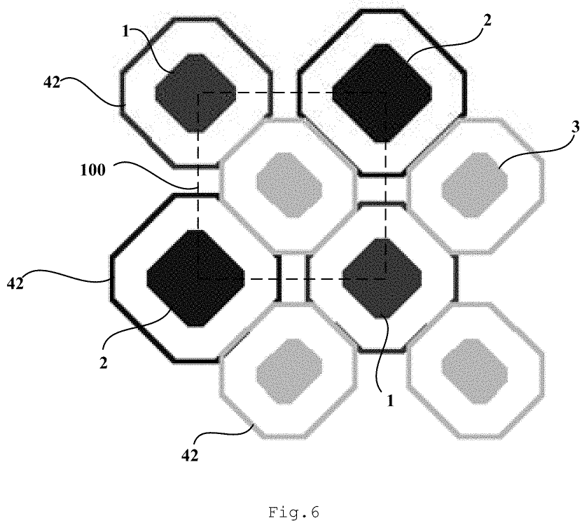

FIG. 6 is a schematic view illustrating a diamond arrangement of some subpixels according to another embodiment of the present disclosure. In this embodiment, the organic material layers of the first subpixel 1, the second subpixel 2 and the third subpixel 3 are respectively prepared by a mask plate evaporation method, each subpixel has the same shape as the corresponding organic material layer and their geometric centers coincide with each other, and an edge of each subpixel is located inside an edge of the corresponding organic material layer; wherein the third subpixel 3 is substantially rectangular, that is, the whole third subpixel 3 is rectangular; four corners of the first subpixel 1, the second subpixel 2 and the third subpixel 3 have oblique chamfers, and the arrangement parameters of the first subpixel 1, the second subpixel 2 and the third subpixel 3 can be determined according to the following relational expressions:

$$\begin{matrix}\{ \begin{matrix}xmR = xeR + pg 1 \\ yetR = \sqrt{2} xeR - \sqrt{2} reR \\ ymtR = \sqrt{2} xmR - \sqrt{2} rmR \\ seR = {xeR}^{2} - 2 {reR}^{2} \\ α rR = seR / 2 p {s}^{2}\end{matrix} & Formula 1 \\ \{ \begin{matrix}xmB = xeB + pg 2 \\ yetB = \sqrt{2} xeB - \sqrt{2} reB \\ ymtB = \sqrt{2} xmB - \sqrt{2} rmB \\ seB = {xeB}^{2} - 2 {reB}^{2} = seR * α B \\ α rB = seB / 2 p {s}^{2}\end{matrix} & Formula 2 \\ \{ \begin{matrix}xmG = xeG + pg 2 \\ ymG = yeG + pg 1 \\ yetG = \sqrt{2} xeG + \frac{yeG - xeG}{\sqrt{2}} - \sqrt{2} reG \\ ymtG = \sqrt{2} xmG + \frac{ymG - xmG}{\sqrt{2}} - \sqrt{2} rmG \\ seG = xeG * yeG - 2 {reG}^{2} = seR * α G \\ α rG = seG / p {s}^{2}\end{matrix} & Formula 3 \\ \{ \begin{matrix}gmRB \geq 0 \\ xmG + xmR \leq \sqrt{2} p s \\ ymG + xmB \leq \sqrt{2} p s\end{matrix} & Formula 4 \\ \{ \begin{matrix}rbR 1 = p s * 2 - ymtR \geq rib \\ rbR 2 = \sqrt{2} p s - xmR \geq rib\end{matrix} & Formula 5 \\ \{ \begin{matrix}rbB 1 = p s * 2 - ymtB \geq rib \\ rbB 2 = \sqrt{2} p s - xmB \geq rib\end{matrix} & Formula 6 \\ \{ \begin{matrix}rbG 1 = p s - ymtG \geq rib \\ rbG 2 = \sqrt{2} p s - xmG \geq rib\end{matrix} & Formula 7 \\ \{ \begin{matrix}xeR \geq slot \\ xeG \geq slot \\ xeB \geq slot\end{matrix} & Formula 8 \\ \{ \begin{matrix}rmR \geq rc \\ rmB \geq rc \\ rmG \geq rc\end{matrix} & Formula 9\end{matrix}$$

The meanings of the parameters are the same as those of the previous embodiment, and thus are omitted here.

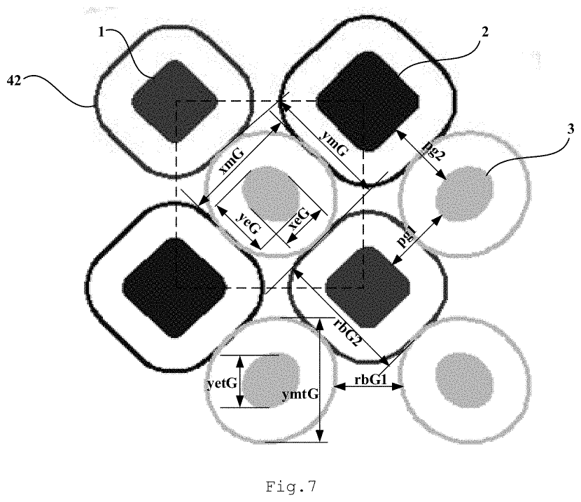

FIG. 7 is a schematic diagram illustrating a diamond arrangement of some subpixels according to still another embodiment of the present disclosure. In this embodiment, the organic material layers of the first subpixel 1, the second subpixel 2 and the third subpixel 3 are respectively prepared by a mask plate evaporation method, each subpixel has the same shape as the corresponding organic material layer and their geometric centers coincide with each other, and an edge of each subpixel is located inside an edge of the corresponding organic material layer; wherein the third subpixel 3 is elliptical; four corners of the first subpixel 1, the second subpixel 2 and the third subpixel 3 have round chamfers, and the arrangement parameters of the first subpixel 1, the second subpixel 2 and the third subpixel 3 can be determined according to the following relational expressions:

$$\begin{matrix}\{ \begin{matrix}xmR = xeR + pg 1 \\ yetR = \sqrt{2} xeR - 2 ( \sqrt{2} - 1 ) * reR \\ ymtR = \sqrt{2} xmR - 2 ( \sqrt{2} - 1 ) * rmR \\ seR = {xeR}^{2} - ( 4 - π ) * {reR}^{2} \\ α rR = seR / 2 p {s}^{2}\end{matrix} & Formula 1 \\ \{ \begin{matrix}xmB = xeB + pg 2 \\ yetB = \sqrt{2} xeB - 2 ( \sqrt{2} - 1 ) * reB \\ ymtB = \sqrt{2} xmB - 2 ( \sqrt{2} - 1 ) * rmB \\ seB = {xeB}^{2} - ( 4 - π ) * {reB}^{2} = seR * α B \\ α rB = seB / 2 p {s}^{2}\end{matrix} & Formula 2 \\ \{ \begin{matrix}xmG = xeG + pg 2 \\ ymG = yeG + pg 1 \\ yetG = \sqrt{\frac{{xeR}^{2} + {xeB}^{2}}{2}} \\ ymtG = \sqrt{\frac{{xmR}^{2} + {xmB}^{2}}{2}} \\ seG = π * xeG * yeG / 4 = seR * α G \\ α rG = seG / p {s}^{2}\end{matrix} & Formula 3 \\ \{ \begin{matrix}gmRB \geq 0 \\ xmG + xmR \leq \sqrt{2} p s \\ ymG + xmB \leq \sqrt{2} p s\end{matrix} & Formula 4 \\ \{ \begin{matrix}rbR 1 = p s * 2 - ymtR \geq rib \\ rbR 2 = \sqrt{2} p s - xmR \geq rib\end{matrix} & Formula 5 \\ \{ \begin{matrix}rbB 1 = p s * 2 - ymtB \geq rib \\ rbB 2 = \sqrt{2} p s - xmB \geq rib\end{matrix} & Formula 6 \\ \{ \begin{matrix}rbG 1 = p s - ymtG \geq rib \\ rbG 2 = \sqrt{2} p s - xmG \geq rib\end{matrix} & Formula 7 \\ \{ \begin{matrix}xeR \geq slot \\ xeG \geq slot \\ xeB \geq slot\end{matrix} & Formula 8 \\ \{ \begin{matrix}rmR \geq rc \\ rmB \geq rc\end{matrix} & Formula 9\end{matrix}$$

wherein xeG is a minor axis length of the third subpixel, yeG is a major axis length of the third subpixel; xmG is a minor axis length of the organic material layer corresponding to the third subpixel, ymG is a major axis length of the organic material layer corresponding to the third subpixel; yetG is an orthographic projection length of the third subpixel in a side direction of the virtual square; ymtG is an orthographic projection length of the organic material layer corresponding to the third subpixel in a side direction of the virtual square. The other parameters have the same meanings as those of the embodiment shown in FIGS. 4a and 4b, and are not repeated here.

FIG. 8 is a schematic diagram illustrating a diamond arrangement of some subpixels according to yet another embodiment of the present disclosure. In this embodiment, the organic material layers of the first subpixel 1, the second subpixel 2 and the third subpixel 3 are respectively prepared by a mask plate evaporation method, each subpixel has the same shape as the corresponding organic material layer and their geometric centers coincide with each other, and an edge of each subpixel is located inside an edge of the corresponding organic material layer; wherein the third subpixel 3 is elliptical; four corners of the first subpixel 1, the second subpixel 2 and the third subpixel 3 have oblique chamfers, and the arrangement parameters of the first subpixel 1, the second subpixel 2 and the third subpixel 3 can be determined according to the following relational expressions:

$$\begin{matrix}\{ \begin{matrix}xmR = xeR + pg 1 \\ yetR = \sqrt{2} xeR - \sqrt{2} reR \\ ymtR = \sqrt{2} xmR - \sqrt{2} rmR \\ seR = {xeR}^{2} - 2 {reR}^{2} \\ α rR = seR / 2 p {s}^{2}\end{matrix} & Formula 1 \\ \{ \begin{matrix}xmB = xeB + pg 2 \\ yetB = \sqrt{2} xeB - \sqrt{2} reB \\ ymtB = \sqrt{2} xmB - \sqrt{2} rmB \\ seB = {xeB}^{2} - 2 {reB}^{2} = seR * α B \\ α rB = seB / 2 p {s}^{2}\end{matrix} & Formula 2 \\ \{ \begin{matrix}xmG = xeG + pg 2 \\ ymG = yeG + pg 1 \\ yetG = \sqrt{\frac{{xeR}^{2} + {xeB}^{2}}{2}} \\ ymtG = \sqrt{\frac{{xmR}^{2} + {xmB}^{2}}{2}} \\ seG = π * xeG * yeG / 4 = seR * α G \\ α rG = seG / p {s}^{2}\end{matrix} & Formula 3 \\ \{ \begin{matrix}gmRB \geq 0 \\ xmG + xmR \leq \sqrt{2} p s \\ ymG + xmB \leq \sqrt{2} p s\end{matrix} & Formula 4 \\ \{ \begin{matrix}rbR 1 = p s * 2 - ymtR \geq rib \\ rbR 2 = \sqrt{2} p s - xmR \geq rib\end{matrix} & Formula 5 \\ \{ \begin{matrix}rbB 1 = p s * 2 - ymtB \geq rib \\ rbB 2 = \sqrt{2} p s - xmB \geq rib\end{matrix} & Formula 6 \\ \{ \begin{matrix}rbG 1 = p s - ymtG \geq rib \\ rbG 2 = \sqrt{2} p s - xmG \geq rib\end{matrix} & Formula 7 \\ \{ \begin{matrix}xeR \geq slot \\ xeG \geq slot \\ xeB \geq slot\end{matrix} & Formula 8 \\ \{ \begin{matrix}rmR \geq rc \\ rmB \geq rc\end{matrix} & Formula 9\end{matrix}$$

wherein xeG is a minor axis length of the third subpixel, yeG is a major axis length of the third subpixel; xmG is a minor axis length of the organic material layer corresponding to the third subpixel, ymG is a major axis length of the organic material layer corresponding to the third subpixel; yetG is an orthographic projection length of the third subpixel in a side direction of the virtual square; ymtG is an orthographic projection length of the organic material layer corresponding to the third subpixel in a side direction of the virtual square. The other parameters have the same meanings as those of the embodiment shown in FIGS. 4a and 4b, and are not repeated here.

Similarly, the arrangement parameters of the subpixels in the embodiments shown in FIG. 6 to FIG. 8 may also be obtained through iterative calculation by the computer, and the iterative principle and process are similar to those in FIG. 5 and thus are not repeated here.

By adopting the subpixel arrangement determining method according to the embodiments of the present disclosure, the subpixel arrangement parameters with the aperture ratio meeting the requirement can be quickly and accurately obtained through computer calculation, and the design efficiency is greatly improved.

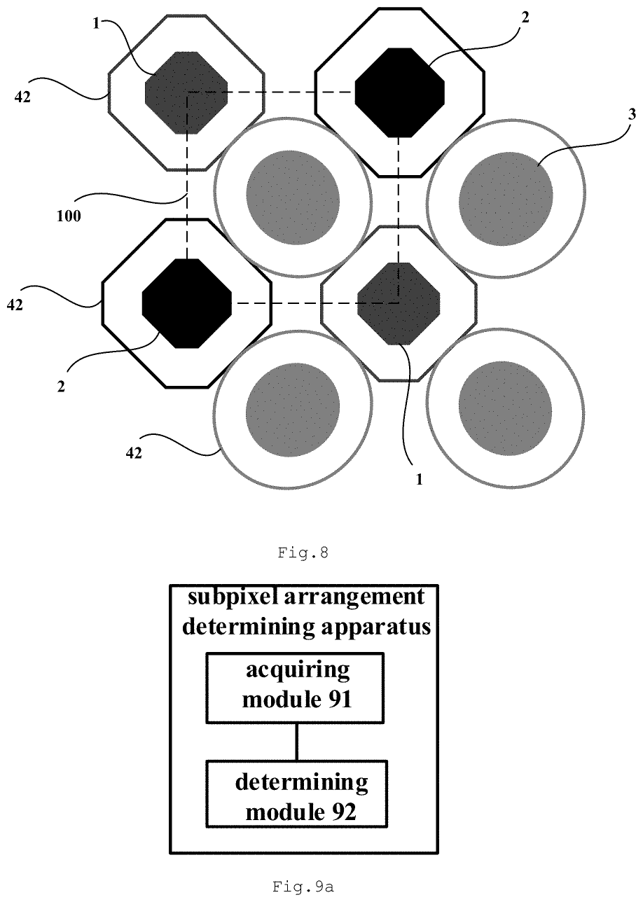

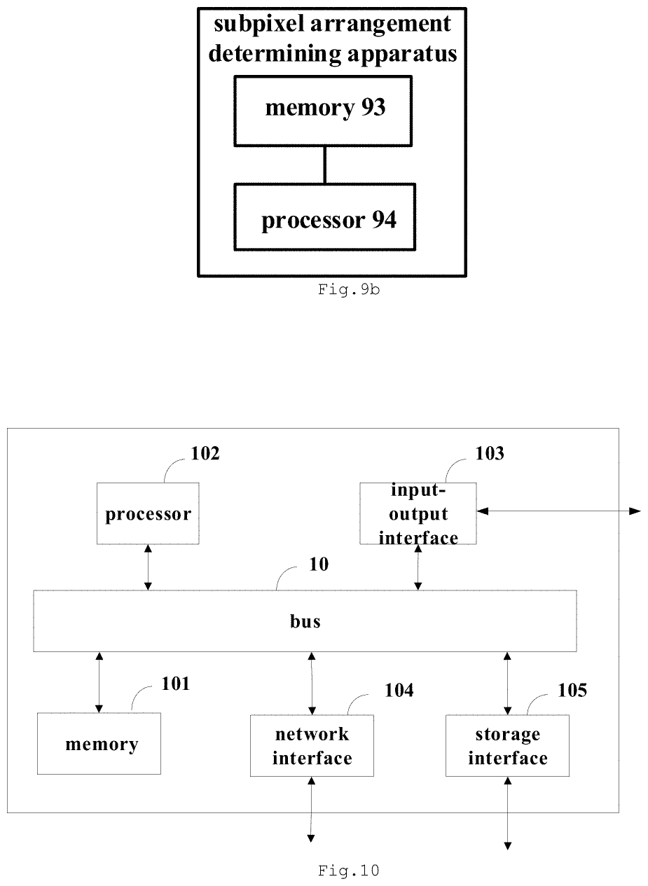

In view of the organic light emitting display panel in which the subpixels are arranged in a diamond as above, as shown in FIG. 9a, an embodiment of the present disclosure further provides an apparatus for determining a subpixel arrangement of an organic light emitting display panel, comprising:
an acquiring module 91 configured to acquire a side length of a virtual square, a spacing between the third subpixel and an adjacent first subpixel, a spacing between the third subpixel and an adjacent second subpixel, a ratio of aperture ratios of the first subpixel, the second subpixel and the third subpixel; and
a determining module 92 configured to determine arrangement parameters of the first subpixel, the second subpixel, and the third subpixel, according to the side length of the virtual square, the spacing between the third subpixel and an adjacent first subpixel, the spacing between the third subpixel and an adjacent second subpixel, the ratio of the aperture ratios of the first subpixel, the second subpixel and the third subpixel, and arrangement constraint conditions of the first subpixel, the second subpixel, and the third subpixel, so that the aperture ratio of the first subpixel is not less than a target aperture ratio.

Similarly, by adopting the subpixel arrangement determining apparatus according to the embodiments of the present disclosure, the subpixel arrangement parameters with the aperture ratio meeting the requirement can be quickly and accurately obtained through computer calculation, and the design efficiency is greatly improved.

As shown in FIG. 9b, some embodiments of the present disclosure further provide an apparatus for determining a subpixel arrangement of an organic light emitting display panel, comprising: a memory 93 and a processor 94 coupled to the memory 93, the processor 94 being configured to perform the subpixel arrangement determining method according to any of the previous embodiments based on instructions stored in the memory 93.

It should be understood that the various steps in the foregoing subpixel arrangement determining method may be implemented by a processor, and may be implemented by any one of software, hardware, firmware, or a combination thereof.

In addition to the subpixel arrangement determining method and apparatus described above, the embodiments of the present disclosure may also take the form of a computer program product embodied on one or more non-volatile storage media containing computer program instructions. Therefore, some embodiments of the present disclosure further provide a computer readable storage medium having stored thereon a computer program, which, when executed by a processor, implements the subpixel arrangement determining method according to any of the previous technical solutions.

FIG. 10 is a schematic diagram illustrating a computer system according to some embodiments of the present disclosure.

As shown in FIG. 10, the computer system may be embodied in the form of a general-purpose computing device, and the computer system may be used to implement the subpixel arrangement determining method of the above-described embodiment. The computer system comprises a memory 101, a processor 102, and a bus 10 that connects the various system components.

The memory 101 may include, for example, a system memory, a non-volatile storage medium, and the like. The system memory stores, for example, an operating system, an application program, a Boot Loader, and other programs. The system memory may include a volatile storage medium, such as Random Access Memory (RAM) and/or cache memory. The non-volatile storage medium stores, for example, instructions to perform corresponding embodiments of the display method. The non-volatile storage medium includes, but is not limited to, magnetic disk storage, optical storage, flash memory, and the like.

The processor 102 may be implemented as discrete hardware components, such as general purpose processors, Digital Signal Processors (DSPs), Application Specific Integrated Circuits (ASICs), Field Programmable Gate Arrays (FPGAs) or other programmable logic devices, discrete gates or transistors, and so forth. Accordingly, each of the modules such as the judging module and the determining module may be implemented by a Central Processing Unit (CPU) executing instructions in a memory to perform the corresponding steps, or may be implemented by a dedicated circuit to perform the corresponding steps.

Bus 10 may use any of a variety of bus structures. For example, the bus structures include, but are not limited to, Industry Standard Architecture (ISA) bus, Micro Channel Architecture (MCA) bus, and Peripheral Component Interconnect (PCI) bus.

The computer system may also include an input/output interface 103, a network interface 104, a storage interface 105, and the like. The input/output interface 103, the network interface 104, the storage interface 105, and the memory 101 and the processor 102 may be connected by the bus 10. The input/output interface 103 may provide a connection interface for an input/output device such as a display, a mouse, and a keyboard. The network interface 104 provides a connection interface for various networking devices. The storage interface 105 provides a connection interface for external storage devices such as a floppy disk, a USB disk, and an SD card.

So far, the embodiments of this disclosure have been described in detail. In order to avoid obscuring the idea of this disclosure, some details well known in the art are omitted. A person skilled in the art can fully understand how to implement the technical solutions disclosed herein according to the above description.

Although some specific embodiments of the present disclosure have been described in detail with examples, it should be understood by a person skilled in the art that the above examples are only intended to be illustrative but not to limit the scope of the present disclosure. Those skilled in the art would appreciate that, the above embodiments can be modified or partial technical features thereof can be equivalently substituted without departing from the scope and spirit of the present disclosure. The scope of the present disclosure is defined by the attached claims.

What is claimed is:

1. A method for determining a subpixel arrangement of an organic light emitting display panel, wherein the organic light emitting display panel comprises a first subpixel, a second subpixel and a third subpixel, the first subpixel and the second subpixel are sequentially arranged at four vertexes of a virtual square in a clockwise direction, the first subpixel and the second subpixel are approximately square and a diagonal line of the first subpixel and a diagonal line of the second subpixel extend along one side of the virtual square, the third subpixel is arranged at a center of the virtual square, the third subpixel has a first symmetry axis extending along one of diagonal lines of the virtual square and a second symmetry axis extending along the other diagonal line of the virtual square,
the method for determining the subpixel arrangement comprising:
determining arrangement parameters of the first subpixel, the second subpixel, and the third subpixel, according to a side length of the virtual square, a spacing between the third subpixel and an adjacent first subpixel, a spacing between the third subpixel and an adjacent second subpixel, a ratio of aperture ratios of the first subpixel, the second subpixel and the third subpixel, and arrangement constraint conditions of the first subpixel, the second subpixel, and the third subpixel, so that the aperture ratio of the first subpixel is not less than a target aperture ratio.

2. The method for determining a subpixel arrangement according to claim 1, wherein the determining of arrangement parameters of the first subpixel, the second subpixel, and the third subpixel so that the aperture ratio of the first subpixel is not less than a target aperture ratio comprises:
determining the arrangement parameters of the first subpixel, the second subpixel, and the third subpixel so that the aperture ratio of the first subpixel is maximized.

3. The method for determining a subpixel arrangement according to claim 1, wherein the determining of arrangement parameters of the first subpixel, the second subpixel, and the third subpixel so that the aperture ratio of the first subpixel is not less than a target aperture ratio comprises:
determining the arrangement parameters of the first subpixel, the second subpixel, and the third subpixel so that the aperture ratios of all the first subpixel, the second subpixel and the third subpixel are maximized.

4. The method for determining a subpixel arrangement according to claim 2, wherein each subpixel of the first subpixel, the second subpixel and the third subpixel respectively has a same shape as and coincident geometric center with the corresponding organic material layer, and an edge of each subpixel is located inside an edge of the corresponding organic material layer.

5. The method for determining a subpixel arrangement according to claim 4, wherein the third subpixel is substantially rectangular or elliptical, and four corners of the first subpixel, the second subpixel have round or oblique chamfers, and the third subpixel have round or oblique chamfers in a case where the third subpixel is substantially rectangular.

6. The method for determining a subpixel arrangement according to claim 4, wherein:
the third subpixel is substantially rectangular, and four corners of the first subpixel, the second subpixel and the third subpixel have round chamfers; and
the arrangement parameters of the first subpixel, the second subpixel and the third subpixel are determined according to the following relational expressions:
$$\begin{matrix}\{ \begin{matrix}xmR = xeR + pg 1 \\ yetR = \sqrt{2} xeR - 2 ( \sqrt{2} - 1 ) * reR \\ ymtR = \sqrt{2} xmR - 2 ( \sqrt{2} - 1 ) * rmR \\ seR = {xeR}^{2} - ( 4 - π ) * {reR}^{2} \\ α rR = seR / 2 p {s}^{2}\end{matrix} & Formula 1 \\ \{ \begin{matrix}xmB = xeB + pg 2 \\ yetB = \sqrt{2} xeB - 2 ( \sqrt{2} - 1 ) * reB \\ ymtB = \sqrt{2} xmB - 2 ( \sqrt{2} - 1 ) * rmB \\ seB = {xeB}^{2} - ( 4 - π ) * {reB}^{2} = seR * α B \\ α rB = seB / 2 p {s}^{2}\end{matrix} & Formula 2 \\ \{ \begin{matrix}xmG = xeG + pg 2 \\ ymG = yeG + pg 1 \\ yetG = \sqrt{2} xeG + \frac{yeG - xeG}{\sqrt{2}} - 2 ( \sqrt{2} - 1 ) * reG \\ ymtG = \sqrt{2} xmG + \frac{ymG - xmG}{\sqrt{2}} - 2 ( \sqrt{2} - 1 ) * rmG \\ seG = xeG * yeG - ( 4 - π ) * {reG}^{2} = seR * α G \\ α rG = seG / p {s}^{2}\end{matrix} & Formula 3 \\ \{ \begin{matrix}gmRB \geq 0 \\ xmG + xmR \leq \sqrt{2} p s \\ ymG + xmB \leq \sqrt{2} p s\end{matrix} & Formula 4 \\ \{ \begin{matrix}rbR 1 = p s * 2 - ymtR \geq rib \\ rbR 2 = \sqrt{2} p s - xmR \geq rib\end{matrix} & Formula 5 \\ \{ \begin{matrix}rbR 1 = p s * 2 - ymtR \geq rib \\ rbR2 = \sqrt{2} p s - xmR \geq rib\end{matrix} & Formula 6 \\ \{ \begin{matrix}rbG 1 = p s - ymtG \geq rib \\ rbG 2 = \sqrt{2} p s - xmG \geq rib\end{matrix} & Formula 7 \\ \{ \begin{matrix}xeR \geq slot \\ xeG \geq slot \\ xeB \geq slot\end{matrix} & Formula 8 \\ \{ \begin{matrix}rmR \geq rc \\ rmB \geq rc \\ rmG \geq rc\end{matrix} & Formula 9\end{matrix}$$
where xeR is a side length of the first subpixel, xeB is a side length of the second subpixel, xeG is a short side length of the third subpixel, and yeG is a long side length of the third subpixel;
xmR is a side length of the organic material layer corresponding to the first subpixel, xmB is a side length of the organic material layer corresponding to the second subpixel, xmG is a short side length of the organic material layer corresponding to the third subpixel, and ymG is a long side length of the organic material corresponding to the third subpixel;
yetR is a diagonal length of the first subpixel, yetB is a diagonal length of the second subpixel, and yetG is a diagonal length of the third subpixel;
ymtR is a diagonal length of the organic material layer corresponding to the first subpixel, ymtB is a diagonal length of the organic material layer corresponding to the second subpixel, and ymtG is a diagonal length of the organic material layer corresponding to the third subpixel;
reR is a value of the chamfers of the first subpixel, reB is a value of the chamfers of the second subpixel, and reG is a value of the chamfers of the third subpixel;
rmR is a value of chamfers of the organic material layer corresponding to the first subpixel, rmB is a value of chamfers of the organic material layer corresponding to the second subpixel, and rmG is a value of chamfers of the organic material layer corresponding to the third subpixel;
SeR is an area of the first subpixel, SeB is an area of the second subpixel, and SeG is an area of the third subpixel;
arR is an aperture ratio of the first subpixel, arB is an aperture ratio of the second subpixel, and arG is an aperture ratio of the third subpixel;
gmRB is a spacing between the organic material layers respectively corresponding to adjacent first subpixel and second subpixel, rbR1 is a spacing between the organic material layers corresponding to two first subpixels adjacent in a row direction, rbR2 is a spacing between the organic material layers corresponding to two first subpixels adjacent in a diagonal direction of the virtual square, rbB1 is a spacing between the organic material layers corresponding to two second subpixels adjacent in the row direction, rbB2 is a spacing between the organic material layers corresponding to two second subpixels adjacent in the diagonal direction of the virtual square, rbG1 is a spacing between the organic material layers corresponding to two third subpixels adjacent in the row direction, and rbG2 is a spacing between the organic material layers corresponding to two third subpixels adjacent in the diagonal direction of the virtual square; and
ps is a side length of the virtual square and is a known quantity, pg1 is a spacing between the third subpixel and an adjacent first subpixel and is a known quantity, pg2 is a spacing between the third subpixel and an adjacent second subpixel and is a known quantity, a ratio of the aperture ratios of the first subpixel, the second subpixel and the third subpixel is 1:aB:aG and is a known quantity, rib is a minimum allowable spacing between two adjacent apertures of the mask plate, slot is a minimum allowable width of an aperture of the mask plate, and rc is a minimum allowable value of chamfers of the aperture of the mask plate.

7. The method for determining a subpixel arrangement according to claim 4, wherein:
the third subpixel is substantially rectangular, and four corners of the first subpixel, the second subpixel and the third subpixel have oblique chamfers; and
the arrangement parameters of the first subpixel, the second subpixel and the third subpixel are determined according to the following relational expressions:
$$\begin{matrix}\{ \begin{matrix}xmR = xeR + pg 1 \\ yetR = \sqrt{2} xeR - \sqrt{2} reR \\ ymtR = \sqrt{2} xmR - \sqrt{2} rmR \\ seR = {xeR}^{2} - 2 {reR}^{2} \\ α rR = seR / 2 p {s}^{2}\end{matrix} & Formula 1 \\ \{ \begin{matrix}xmB = xeB + pg 2 \\ yetB = \sqrt{2} xeB - \sqrt{2} reB \\ ymtB = \sqrt{2} xmB - \sqrt{2} rmB \\ seB = {xeB}^{2} - 2 {reB}^{2} = seR * α B \\ α rB = seB / 2 p {s}^{2}\end{matrix} & Formula 2 \\ \{ \begin{matrix}xmG = xeG + pg 2 \\ ymG = yeG + pg 1 \\ yetG = \sqrt{2} xeG + \frac{yeG - xeG}{\sqrt{2}} - \sqrt{2} reG \\ ymtG = \sqrt{2} xmG + \frac{ymG - xmG}{\sqrt{2}} - \sqrt{2} rmG \\ seG = xeG * yeG - 2 {reG}^{2} = seR * α G \\ α rG = seG / p {s}^{2}\end{matrix} & Formula 3 \\ \{ \begin{matrix}gmRB \geq 0 \\ xmG + xmR \leq \sqrt{2} p s \\ ymG + xmB \leq \sqrt{2} p s\end{matrix} & Formula 4 \\ \{ \begin{matrix}rbR 1 = p s * 2 - ymtR \geq rib \\ rbR 2 = \sqrt{2} p s - xmR \geq rib\end{matrix} & Formula 5 \\ \{ \begin{matrix}rbB 1 = p s * 2 - ymtB \geq rib \\ rbB 2 = \sqrt{2} p s - xmB \geq rib\end{matrix} & Formula 6 \\ \{ \begin{matrix}rbG 1 = p s - ymtG \geq rib \\ rbG 2 = \sqrt{2} p s - xmG \geq rib\end{matrix} & Formula 7 \\ \{ \begin{matrix}xeR \geq slot \\ xeG \geq slot \\ xeB \geq slot\end{matrix} & Formula 8 \\ \{ \begin{matrix}rmR \geq rc \\ rmB \geq rc \\ rmG \geq rc\end{matrix} & Formula 9\end{matrix}$$
where xeR is a side length of the first subpixel, xeB is a side length of the second subpixel, xeG is a short side length of the third subpixel, and yeG is a long side length of the third subpixel;
xmR is a side length of the organic material layer corresponding to the first subpixel, xmB is a side length of the organic material layer corresponding to the second subpixel, xmG is a short side length of the organic material layer corresponding to the third subpixel, and ymG is a long side length of the organic material layer corresponding to the third subpixel;
yetR is a diagonal length of the first subpixel, yetB is a diagonal length of the second subpixel, and yetG is a diagonal length of the third subpixel;
ymtR is a diagonal length of the organic material layer corresponding to the first subpixel, ymtB is a diagonal length of the organic material layer corresponding to the second subpixel, and ymtG is a diagonal length of the organic material layer corresponding to the third subpixel;
reR is a value of the chamfers of the first subpixel, reB is a value of the chamfers of the second subpixel, and reG is a value of the chamfers of the third subpixel;
rmR is a value of chamfers of the organic material layer corresponding to the first subpixel, rmB is a value of chamfers of the organic material layer corresponding to the second subpixel, and rmG is a value of chamfers of the organic material layer corresponding to the third subpixel;
SeR is an area of the first subpixel, SeB is an area of the second subpixel, and SeG is an area of the third subpixel;
arR is an aperture ratio of the first subpixel, arB is an aperture ratio of the second subpixel, and arG is an aperture ratio of the third subpixel;
gmRB is a spacing between the organic material layers respectively corresponding to adjacent first subpixel and second subpixel, rbR1 is a spacing between the organic material layers corresponding to two first subpixels adjacent in a row direction, rbR2 is a spacing between the organic material layers corresponding to two first subpixels adjacent in a diagonal direction of the virtual square, rbB1 is a spacing between the organic material layers corresponding to two second subpixels adjacent in the row direction, rbB2 is a spacing between the organic material layers corresponding to two second subpixels adjacent in the diagonal direction of the virtual square, rbG1 is a spacing between the organic material layers corresponding to two third subpixels adjacent in the row direction, and rbG2 is a spacing between the organic material layers corresponding to two third subpixels adjacent in the diagonal direction of the virtual square; and
ps is a side length of the virtual square and is a known quantity, pg1 is a spacing between the third subpixel and an adjacent first subpixel and is a known quantity, pg2 is a spacing between the third subpixel and an adjacent second subpixel and is a known quantity, a ratio of the aperture ratios of the first subpixel, the second subpixel and the third subpixel is 1:aB:aG and is a known quantity, rib is a minimum allowable spacing between two adjacent apertures of the mask plate, slot is a minimum allowable width of an aperture of the mask plate, and rc is a minimum allowable value of chamfers of the aperture of the mask plate.

8. The method for determining a subpixel arrangement according to claim 4, wherein:
the third subpixel is elliptical, and four corners of the first subpixel and the second subpixel have round chamfers; and
the arrangement parameters of the first subpixel, the second subpixel and the third subpixel can be determined according to the following relational expressions:
$$\begin{matrix}\{ \begin{matrix}xmR = xeR + pg 1 \\ yetR = \sqrt{2} xeR - 2 ( \sqrt{2} - 1 ) * reR \\ ymtR = \sqrt{2} xmR - 2 ( \sqrt{2} - 1 ) * rmR \\ seR = {xeR}^{2} - ( 4 - π ) * {reR}^{2} \\ α rR = seR / 2 p {s}^{2}\end{matrix} & Formula 1 \\ \{ \begin{matrix}xmB = xeB + pg 2 \\ yetB = \sqrt{2} xeB - 2 ( \sqrt{2} - 1 ) * reB \\ ymtB = \sqrt{2} xmB - 2 ( \sqrt{2} - 1 ) * rmB \\ seB = {xeB}^{2} - ( 4 - π ) * {reB}^{2} = seR * α B \\ α rB = seB / 2 p {s}^{2}\end{matrix} & Formula 2 \\ \{ \begin{matrix}xmG = xeG + pg 2 \\ ymG = yeG + pg 1 \\ yetG = \sqrt{\frac{{xeR}^{2} + {xeB}^{2}}{2}} \\ ymtG = \sqrt{\frac{{xmR}^{2} + {xmB}^{2}}{2}} \\ seG = π * xeG * yeG / 4 = seR * α G \\ α rG = seG / p {s}^{2}\end{matrix} & Formula 3 \\ \{ \begin{matrix}gmRB \geq 0 \\ xmG + xmR \leq \sqrt{2} p s \\ ymG + xmB \leq \sqrt{2} p s\end{matrix} & Formula 4 \\ \{ \begin{matrix}rbR 1 = p s * 2 - ymtR \geq rib \\ rbR 2 = \sqrt{2} p s - xmR \geq rib\end{matrix} & Formula 5 \\ \{ \begin{matrix}rbB 1 = p s * 2 - ymtB \geq rib \\ rbB 2 = \sqrt{2} p s - xmB \geq rib\end{matrix} & Formula 6 \\ \{ \begin{matrix}rbG 1 = p s - ymtG \geq rib \\ rbG 2 = \sqrt{2} p s - xmG \geq rib\end{matrix} & Formula 7 \\ \{ \begin{matrix}xeR \geq slot \\ xeG \geq slot \\ xeB \geq slot\end{matrix} & Formula 8 \\ \{ \begin{matrix}rmR \geq rc \\ rmB \geq rc\end{matrix} & Formula 9\end{matrix}$$
wherein xeR is a side length of the first subpixel, xeB is a side length of the second subpixel, xeG is a minor axis length of the third subpixel, yeG is a major axis length of the third subpixel;
xmR is a side length of the organic material layer corresponding to the first subpixel, xmB is a side length of the organic material layer corresponding to the second subpixel, xmG is a minor axis length of the organic material layer corresponding to the third subpixel, ymG is a major axis length of the organic material layer corresponding to the third subpixel;
yetR is a diagonal length of the first subpixel, yetB is a diagonal length of the second subpixel, and yetG is an orthographic projection length of the third subpixel in a side direction of the virtual square;
ymtR is a diagonal length of the organic material layer corresponding to the first subpixel, ymtB is a diagonal length of the organic material layer corresponding to the second subpixel, and ymtG is an orthographic projection length of the organic material layer corresponding to the third subpixel in a side direction of the virtual square;
reR is a value of the chamfers of the first subpixel, reB is a value of the chamfers of the second subpixel;
rmR is a value of chamfers of the organic material layer corresponding to the first subpixel, rmB is a value of chamfers of the organic material layer corresponding to the second subpixel;
SeR is an area of the first subpixel, SeB is an area of the second subpixel, and SeG is an area of the third subpixel;
arR is an aperture ratio of the first subpixel, arB is an aperture ratio of the second subpixel, and arG is an aperture ratio of the third subpixel;
gmRB is a spacing between the organic material layers respectively corresponding to adjacent first subpixel and second subpixel, rbR1 is a spacing between the organic material layers corresponding to two first subpixels adjacent in a row direction, rbR2 is a spacing between the organic material layers corresponding to two first subpixels adjacent in a diagonal direction of the virtual square, rbB1 is a spacing between the organic material layers corresponding to two second subpixels adjacent in the row direction, rbB2 is a spacing between the organic material layers corresponding to two second subpixels adjacent in the diagonal direction of the virtual square, rbG1 is a spacing between the organic material layers corresponding to two third subpixels adjacent in the row direction, and rbG2 is a spacing between the organic material layers corresponding to two third subpixels adjacent in the diagonal direction of the virtual square; and
ps is a side length of the virtual square and is a known quantity, pg1 is a spacing between the third subpixel and an adjacent first subpixel and is a known quantity, pg2 is a spacing between the third subpixel and an adjacent second subpixel and is a known quantity, a ratio of the aperture ratios of the first subpixel, the second subpixel and the third subpixel is 1:aB:aG and is a known quantity, rib is a minimum allowable spacing between two adjacent apertures of the mask plate, slot is a minimum allowable width of an aperture of the mask plate, and rc is a minimum allowable value of chamfers of the aperture of the mask plate.

9. The method for determining a subpixel arrangement according to claim 4, wherein:
the third subpixel is elliptical, and four corners of the first subpixel and the second subpixel have oblique chamfers; and
the arrangement parameters of the first subpixel, the second subpixel and the third subpixel are determined according to the following relational expressions:
$$\begin{matrix}\{ \begin{matrix}xmR = xeR + pg 1 \\ yetR = \sqrt{2} xeR - \sqrt{2} reR \\ ymtR = \sqrt{2} xmR - \sqrt{2} rmR \\ seR = {xeR}^{2} - 2 {reR}^{2} \\ α rR = seR / 2 p {s}^{2}\end{matrix} & Formula 1 \\ \{ \begin{matrix}xmB = xeB + pg 2 \\ yetB = \sqrt{2} xeB - \sqrt{2} reB \\ ymtB = \sqrt{2} xmB - \sqrt{2} rmB \\ seB = {xeB}^{2} - 2 {reB}^{2} = seR * α B \\ α rB = seB / 2 p {s}^{2}\end{matrix} & Formula 2 \\ \{ \begin{matrix}xmG = xeG + pg 2 \\ ymG = yeG + pg 1 \\ yetG = \sqrt{\frac{{xeR}^{2} + {xeB}^{2}}{2}} \\ ymtG = \sqrt{\frac{{xmR}^{2} + {xmB}^{2}}{2}} \\ seG = π * xeG * yeG / 4 = seR * α G \\ α rG = seG / p {s}^{2}\end{matrix} & Formula 3 \\ \{ \begin{matrix}gmRB \geq 0 \\ xmG + xmR \leq \sqrt{2} p s \\ ymG + xmB \leq \sqrt{2} p s\end{matrix} & Formula 4 \\ \{ \begin{matrix}rbR 1 = p s * 2 - ymtR \geq rib \\ rbR 2 = \sqrt{2} p s - xmR \geq rib\end{matrix} & Formula 5 \\ \{ \begin{matrix}rbB 1 = p s * 2 - ymtB \geq rib \\ rbB 2 = \sqrt{2} p s - xmB \geq rib\end{matrix} & Formula 6 \\ \{ \begin{matrix}rbG 1 = p s - ymtG \geq rib \\ rbG 2 = \sqrt{2} p s - xmG \geq rib\end{matrix} & Formula 7 \\ \{ \begin{matrix}xeR \geq slot \\ xeG \geq slot \\ xeB \geq slot\end{matrix} & Formula 8 \\ \{ \begin{matrix}rmR \geq rc \\ rmB \geq rc\end{matrix} & Formula 9\end{matrix}$$
where xeR is a side length of the first subpixel, xeB is a side length of the second subpixel, xeG is a minor axis length of the third subpixel, yeG is a major axis length of the third subpixel;
xmR is a side length of the organic material layer corresponding to the first subpixel, xmB is a side length of the organic material layer corresponding to the second subpixel, xmG is a minor axis length of the organic material layer corresponding to the third subpixel, ymG is a major axis length of the organic material layer corresponding to the third subpixel;
yetR is a diagonal length of the first subpixel, yetB is a diagonal length of the second subpixel, and yetG is an orthographic projection length of the third subpixel in a side direction of the virtual square;
ymtR is a diagonal length of the organic material layer corresponding to the first subpixel, ymtB is a diagonal length of the organic material layer corresponding to the second subpixel, and ymtG is an orthographic projection length of the organic material layer corresponding to the third subpixel in a side direction of the virtual square;
reR is a value of the chamfers of the first subpixel, reB is a value of the chamfers of the second subpixel;
rmR is a value of chamfers of the organic material layer corresponding to the first subpixel, rmB is a value of chamfers of the organic material layer corresponding to the second subpixel;
SeR is an area of the first subpixel, SeB is an area of the second subpixel, and SeG is an area of the third subpixel;
arR is an aperture ratio of the first subpixel, arB is an aperture ratio of the second subpixel, and arG is an aperture ratio of the third subpixel;
gmRB is a spacing between the organic material layers respectively corresponding to adjacent first subpixel and second subpixel, rbR1 is a spacing between the organic material layers corresponding to two first subpixels adjacent in a row direction, rbR2 is a spacing between the organic material layers corresponding to two first subpixels adjacent in a diagonal direction of the virtual square, rbB1 is a spacing between the organic material layers corresponding to two second subpixels adjacent in the row direction, rbB2 is a spacing between the organic material layers corresponding to two second subpixels adjacent in the diagonal direction of the virtual square, rbG1 is a spacing between the organic material layers corresponding to two third subpixels adjacent in the row direction, and rbG2 is a spacing between the organic material layers corresponding to two third subpixels adjacent in the diagonal direction of the virtual square; and
ps is a side length of the virtual square and is a known quantity, pg1 is a spacing between the third subpixel and an adjacent first subpixel and is a known quantity, pg2 is a spacing between the third subpixel and an adjacent second subpixel and is a known quantity, a ratio of the aperture ratios of the first subpixel, the second subpixel and the third subpixel is 1:aB:aG and is a known quantity, rib is a minimum allowable spacing between two adjacent apertures of the mask plate, slot is a minimum allowable width of an aperture of the mask plate, and rc is a minimum allowable value of chamfers of the aperture of the mask plate.

10. The method for determining a subpixel arrangement according to claim 1, wherein the arrangement parameters of the first subpixel, the second subpixel and the third subpixel are obtained through iterative computation of a computer.

11. The method for determining a subpixel arrangement according to claim 1, wherein the first subpixel is a red subpixel, the second subpixel is a blue subpixel, and the third subpixel is a green subpixel.

12. The method for determining a subpixel arrangement according to claim 1, wherein the subpixels of the organic light emitting display panel are in a diamond arrangement.

13. The method for determining a subpixel arrangement according to claim 12, wherein the organic light emitting display panel comprises a plurality of pixel units, and each virtual square corresponds to one pixel unit of the organic light emitting display panel.

14. The method for determining a subpixel arrangement according to claim 13, wherein each pixel unit comprises two ¼-area first subpixels, two ¼-area second subpixels, and one complete third subpixel.

15. A method for manufacturing an organic light emitting display panel, comprising:
determining the arrangement parameters of the first subpixel, the second subpixel and the third subpixel according to the method for determining a subpixel arrangement of claim 4;
determining characteristic parameters of a mask plate used for evaporating an organic material layer corresponding to each subpixel of the first subpixel, the second subpixel and the third subpixel, according to the determined arrangement parameters; and
respectively forming the organic material layer corresponding to each subpixel using the mask plate having the determined characteristic parameters.

16. The manufacturing method according to claim 15, wherein the characteristic parameters of the mask plate comprise an aperture dimension and a value of chamfers of the mask plate.

17. An organic light emitting display panel obtained according to the manufacturing method of claim 15.

18. An apparatus for determining a subpixel arrangement of an organic light emitting display panel, comprising:
a memory, and
a processor coupled to the memory, the processor configured to perform the method for determining a subpixel arrangement according to claim 1 based on instructions stored in the memory.

19. A non-transient computer readable storage medium having stored thereon a computer program, which when executed by a processor, implements the method for determining a subpixel arrangement according to claim 1.
